(19) United States
(12) Patent Application Publication
(10) Pub. No.: US 2007/0164303 A1
(43) Pub. Date: Jul. 19, 2007

(54) [LED LAMP]

(75) Inventor: Ying-Ming Ho, TAIPEI (TW)

Correspondence Address: LIGHTOP TECHNOLOGY CO., LTD., P.O. BOX 108-00403, TAIPEI, TW

(73) Assignee: LIGHTOP TECHNOLOGY CO., LTD., Chung-Ho City (TW)

(21) Appl. No.: 11/306,862

(22) Filed: Jan. 13, 2006

(51) Int. Cl. H01L 33/00

(52) U.S. Cl. 257/99

(57) ABSTRACT

A LED lamp includes a substrate, which has through holes cut through the top wall and bottom wall thereof and electric contacts fixedly provided at the top wall corresponding to the through holes for connection to power source, metal locating blocks respectively fixedly mounted in the through holes inside the substrate and carry a respective LED (light emitting diode) chips in each through hole of the substrate, and lead wires respectively electrically coupled between the LED chips at the locating blocks and the contacts at the substrate for guiding electric current from the contacts to the LED chips.

### BACKGROUND OF THE INVENTION

1. Field of the Invention

The present invention relates to LED lamps and more particularly, to an improved structure of LED lamp that enhances the light intensity and dissipates heat quickly during operation.

2. Description of the Related Art

FIG. 7 shows a LED lamp according to the prior art. According to this design, the LED lamp comprises a printed circuit board A1, at least one LED (light emitting diode) A2 respectively installed in the printed circuit board A1. and a resin package (not shown) covering the least one LED and the printed circuit board A1. Each LED A2 has metal (iron or copper) frame members A11 inserted through the top and bottom walls of the printed circuit board A1 and fixedly fastened to the bottom wall of the printed circuit board A1 with tin solder A12. Because the metal frame members A11 is sealed in the resin (epoxy resin) package, heat produced during the operation of the LED A2 cannot be quickly dissipated into the outside air.

FIG. 8 shows another structure of LED lamp according to the prior art. According to this design, the LED lamp comprises a printed circuit board B1, a plurality of LEDs B2, lead wires B3, and a reflective cover B4. The printed circuit board B1 has contacts B11. The lead wires B3 couples the LEDs B2 to the contacts B11 of the printed circuit board B1. The reflective cover B4 condenses the light of the LEDs B2. The fabrication process of this design of LED lamp is complicated, resulting in a high manufacturing cost.

Therefore, it is desirable to provide a LED lamp that eliminates the drawbacks of the aforesaid prior art designs.

### SUMMARY OF THE INVENTION

The present invention has been accomplished under the circumstances in view. It is therefore the main object of the present invention to provide a LED lamp, which provides a high light intensity. It is another object of the present invention to provide a LED lamp, which dissipates heat quickly during the operation. It is still another object of the present invention to provide a LED lamp, which is inexpensive to manufacture.

To achieve these and other objects of the present invention, the LED lamp comprises a substrate, which has plurality of through holes cut through the top wall and bottom wall thereof and a plurality of electric contacts fixedly provided at the top wall corresponding to the through holes for connection to power source, a plurality of locating blocks respectively fixedly mounted in the through holes inside the substrate, a plurality of LED (light emitting diode) chips respectively installed in the locating blocks inside the through holes of the substrate, and a plurality of lead wires respectively electrically coupled between the LED chips and the contacts at the substrate for guiding electric current from the contacts to the LED chips. Further, the locating blocks are metal block members for quick dissipation of heat from the LED chips during operation of the LED chips. Further, the peripheral wall of each through hole of the substrate and the top wall of each locating block that carries the associating LED chip are respectively coated with a layer of reflective metal coating for reflecting the light of the LED chips, enhancing the light intensity.

### BRIEF DESCRIPTION OF THE DRAWINGS

FIG. 1 is a schematic sectional elevation of a LED lamp according to a first embodiment of the present invention.

FIG. 2 is a sectional view in an enlarged scale of the LED lamp according to the first embodiment of the present invention.

FIG. 3 is a schematic drawing showing a status of use of the LED lamp according to the first embodiment of the present invention.

FIG. 4 is a sectional view of a LED lamp according to a second embodiment of the present invention.

FIG. 5 is a schematic sectional elevation of a LED lamp according to a third embodiment of the present invention.

FIG. 6 is a sectional view in an enlarged scale of the LED lamp according to the third embodiment of the present invention.

FIG. 7 is a sectional view showing the structure of a LED lamp according to the prior art.

FIG. 8 is a schematic drawing showing another structure of LED lamp according to the prior art.

### DETAILED DESCRIPTION OF THE PREFERRED EMBODIMENT

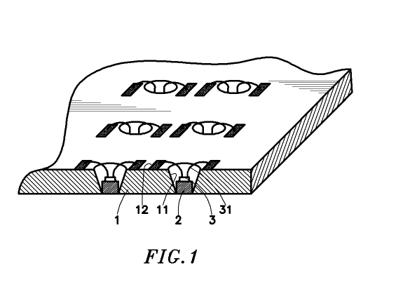

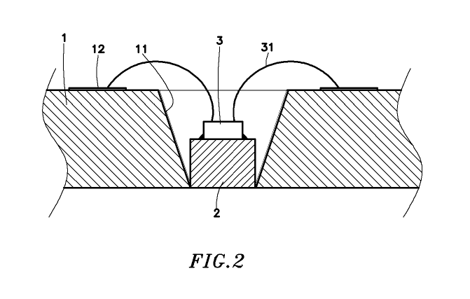

Referring to FIGS. 1 and 2, a LED lamp in accordance with the first embodiment of the present invention is shown comprising a substrate 1, a plurality of locating blocks 2, a plurality of LED (light emitting diode) chips 3, and lead wires 31. The substrate 1 can be a printed circuit board, having a plurality of through holes 11 cut through the top and bottom walls thereof, and a plurality of contacts 12 respectively provided at the top wall adjacent to the through holes 11. The LED chips 3 are respectively mounted on the locating blocks 2 that are respectively affixed to the through holes 11 to hold the respective LED chips 3 inside the associating through holes 11. The lead wires 31 are respectively electrically coupled between the LED chips 3 and the contacts 1 2 at the substrate 1.

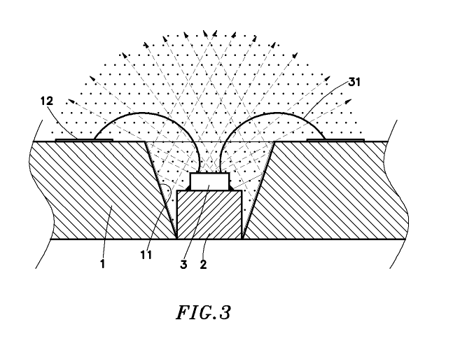

Referring to FIG. 3, the lead wires 31 couple the contacts 12 to the LED chips 3. According to the present invention, the lead wires 31 can be gold wires or aluminum wires. When electric current is connected to the contacts 12, the LED chips 3 are causes to emit light, and the peripheral wall of each through hole 11 concentrates the light of the associating LED chip 3. Further, the through holes 11 have the respective diameter made gradually increased from the bottom wall of the substrate 1 toward the top wall of the substrate 1.

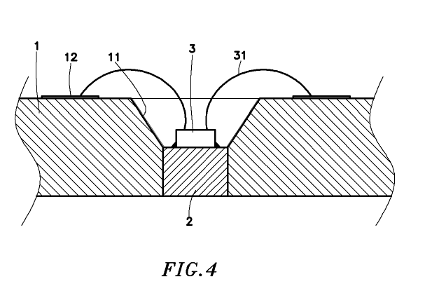

FIG. 4 is a sectional view of a LED lamp according to the second embodiment of the present invention. This embodiment is substantially similar to the aforesaid first embodiment with the exception of the shape of the through holes 11. According to this embodiment, each through hole 11 has a cylindrical shape extending in direction of the bottom wall of the substrate 1 toward the top wall of the substrate 1 to a certain distance and then gradually increased in diameter toward the top wall of the substrate 2.

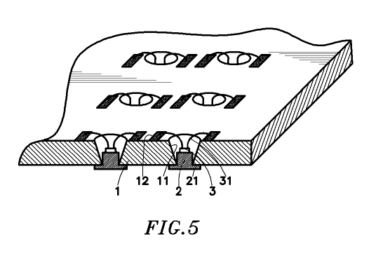

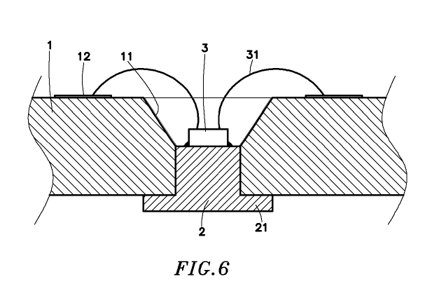

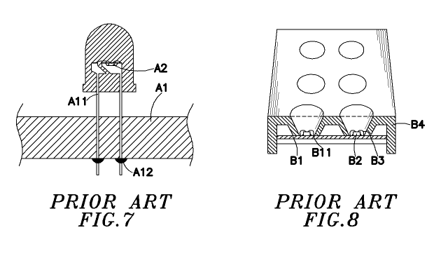

FIGS. 5 and 6 show a LED lamp according to the third embodiment of the present invention. According to this embodiment, each locating block 2 has a bottom flange 21 abutted against the bottom wall of the substrate 1 outside the associating through hole 11.

In the aforesaid various embodiments of the present invention, the locating blocks 2 are metal block members that dissipate heat from the associating LED chips 3 during the operation of the LED chips 3.

Further, the peripheral wall of each through hole 11 and the top wall of each locating block 2 that carries the associating LED chip 3 may be covered with a layer of reflective metal coating for reflecting the light of the LED chips 3 to enhance the intensity of the light. The reflective metal coating can be silver or tin.

As indicated above, the invention provides a LED lamp, which has the following features.

1. The metal locating blocks 2 carry the associating LED chips 3 in the associating through holes 11 at the substrate 1, enabling more amount of electric current to be transmitted to the LED chips 3 and heat to be quickly dissipated from the LED chips 3.

2. The peripheral wall of each through hole 11 gathers the light of the associating LED chip 3, enhancing the light intensity of the LED lamp.

3. The peripheral wall of each through hole 11 is coated with a layer of reflective metal coating to reflect the light of the associate LED chip 3. Therefore, this design eliminates the use of a complicated external reflector means.

A prototype of LED lamp has been constructed with the features of the annexed drawings of FIGS. 1˜6. The LED lamp functions smoothly to provide all of the features discussed earlier.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A LED lamp comprising:
a substrate, said substrate having a top wall, a bottom wall, a plurality of through holes cut through said top wall and said bottom wall, and a plurality of electric contacts fixedly provided at said top wall corresponding to said through holes for connection to power source;
a plurality of locating blocks respectively fixedly mounted in said through holes inside said substrate;
a plurality of LED (light emitting diode) chips respectively installed in said locating blocks inside said through holes of said substrate; and
a plurality of lead wires respectively electrically coupled between said LED chips and said contacts for guiding electric current from said contacts to said LED chips.

2. The LED lamp as claimed in claim 1, wherein said substrate is a printed circuit board.

3. The LED lamp as claimed in claim 1, wherein said through holes each have a diameter gradually increased from said bottom wall toward said top wall.

4. The LED lamp as claimed in claim 1, wherein said through holes each have a cylindrical shape extending in direction of the bottom wall of said substrate toward the top wall of said substrate to a predetermined distance and then gradually increased in diameter toward the top wall of said substrate.

5. The LED lamp as claimed in claim 1, wherein said locating blocks each have a bottom flange abutted against the bottom wall of said substrate outside said through holes.

6. The LED lamp as claimed in claim 1, wherein said locating blocks are metal block members.

7. The LED lamp as claimed in claim 1, wherein said lead wires are gold wires.

8. The LED lamp as claimed in claim 1, wherein said lead wires are aluminum wires.

9. The LED lamp as claimed in claim 1, wherein said through holes of said substrate are respectively peripherally coated with a layer of reflective metal coating.

10. The LED lamp as claimed in claim 9, wherein said reflective metal coating is silver.

11. The LED lamp as claimed in claim 9, wherein said reflective metal coating is tin.

12. The LED lamp as claimed in claim 1, wherein said locating blocks each have a mounting side carrying one of said LED chips and a layer of reflective metal coating coated on said mounting side.

13. The LED lamp as claimed in claim 12, wherein said reflective metal coating is silver.

14. The LED lamp as claimed in claim 12, wherein said reflective metal coating is tin.
